(19) United States
(12) Patent Application Publication
(10) Pub. No.: US 2026/0344313 A1
(43) Pub. Date: Oct. 29, 2026

(54) SUBSTRATE PROCESSING METHOD, BONDED SUBSTRATE PROCESSING METHOD, AND CHIP MANUFACTURING METHOD

(71) Applicant: DISCO CORPORATION, Tokyo (JP)

(72) Inventors: Hayato TANAKA, Tokyo (JP); Hayato IGA, Tokyo (JP); Sungjun CHO, Tokyo (JP)

(21) Appl. No.: 19/640,591

(22) Filed: Apr. 7, 2026

(30) Foreign Application Priority Data
Apr. 23, 2025 (JP) 2025-071253

(51) Int. Cl. H10P 34/42; B23K 26/352; H10P 58/00

(52) U.S. Cl. CPC H10P 34/42; B23K 26/352; H10P 58/00

(57) ABSTRACT

A substrate processing method for processing a substrate having one surface and another surface includes forming a first modified layer in a first annular region included in the substrate, by applying a laser beam having a wavelength transmittable through a material of the substrate to the substrate from the one surface side in such a manner that a focused spot on which the laser beam is focused is positioned in the first annular region, and forming a second modified layer in a second annular region that is remoter from a center of the substrate than the first annular region and that is included in the substrate, by applying the laser beam to the substrate from the one surface side in such a manner that the focused spot is positioned in the second annular region.

### BACKGROUND OF THE INVENTION

### Field of the Invention

The present invention relates to a substrate processing method for processing a substrate having one surface positioned at one end in a thickness direction and another surface positioned at another end, a bonded substrate processing method for processing a bonded substrate including the substrate (first substrate) and a second substrate bonded to the other surface side of the first substrate directly or via a bonding layer, and a chip manufacturing method for manufacturing chips by dividing a workpiece including the substrate.

### Description of the Related Art

Chips of devices such as integrated circuits (ICs) or memories are typically manufactured with use of a substrate shaped as a circular plate made of a semiconductor material such as silicon (Si). Specifically, chips are manufactured by forming a plurality of devices on the front surface side of a substrate in such a manner that the plurality of devices are arranged in a matrix and then dividing the substrate along boundaries of the plurality of devices. Further, chips may be manufactured with use of a bonded substrate including a plurality of substrates for the purpose of, for example, achieving a higher level of circuit integration.

Division of a workpiece such as a single substrate or a bonded substrate is performed in a processing apparatus such as a cutting apparatus, a laser processing apparatus, or a plasma etching apparatus. Note that, in a case where such a processing apparatus is used to divide a workpiece and thus manufacture chips, a portion in the vicinity of a side surface of the workpiece may be scattered as residuals. Further, if scattered residuals collide with components of the processing apparatus, there is a risk that the components are damaged.

In view of this, in a case where chips are manufactured by dividing a workpiece as described above, the workpiece may be processed in such a manner that a portion in the vicinity of a side surface of the workpiece is removed prior to the division of the workpiece (for example, see Japanese Patent Laid-open No. 2010-225976). For example, the portion in the vicinity of the side surface of the workpiece is removed by bringing an annular cutting blade (cutting stone) or a plurality of grindstones provided to a grinding wheel in a state of being dispersed in an annular pattern into contact with the above-described portion while the plurality of grindstones are being rotated.

### SUMMARY OF THE INVENTION

A processing tool such as a cutting blade or a plurality of grindstones included in a grinding wheel is worn every time it is used, and when being severely worn, it needs to be replaced. Accordingly, in a case where a portion in the vicinity of a side surface of a workpiece is removed by the processing tool prior to the division of the workpiece, processing cost is increased.

Further, in a case where the processing tool is brought into contact with the workpiece in such a manner that the portion in the vicinity of the side surface of the workpiece is removed, there is a risk that cracks reaching a plurality of devices are formed due to a strong force acting locally on the workpiece. In order to prevent such cracks from being formed, it is necessary to slow down processing speed (moving speed of a processing point (point of contact between the workpiece and the processing tool)). Accordingly, in a case where the portion in the vicinity of the side surface is removed by the processing tool prior to the division of the workpiece, the processing time is prolonged.

In view of the above circumstances, it is an object of the present invention to provide a substrate processing method, a bonded substrate processing method, and a chip manufacturing method that can prevent a portion in the vicinity of a side surface of a workpiece from being scattered as residuals and prevent increase in processing cost and processing time.

Specifically, in accordance with an aspect of the present invention, there is provided a substrate processing method for processing a substrate having one surface positioned at one end in a thickness direction and another surface positioned at another end. The substrate processing method includes forming a first modified layer in a first annular region included in the substrate, by applying a laser beam having a wavelength transmittable through a material of the substrate to the substrate from the one surface side in such a manner that a focused spot on which the laser beam is focused is positioned in the first annular region, and forming a second modified layer in a second annular region that is remoter from a center of the substrate than the first annular region and that is included in the substrate, by applying the laser beam to the substrate from the one surface side in such a manner that the focused spot is positioned in the second annular region. By the first modified layer and the second modified layer being formed, a crack developed from the first modified layer to the second modified layer is formed.

Incidentally, the first modified layer may include a plurality of first modified portions whose positions in the thickness direction and whose positions in a radial direction perpendicular to the thickness direction are different from each other in a cross section parallel to the thickness direction, the second modified layer may include a plurality of second modified portions whose positions in the thickness direction and whose positions in the radial direction are different from each other in the cross section, and one of the plurality of first modified portions that is closest to the other surface may be closer to the other surface than one of the plurality of second modified portions that is closest to the one surface. Further, the plurality of first modified portions may be arrayed, in the cross section, along a first virtual straight line, and the plurality of second modified portions may be arrayed, in the cross section, along a second virtual straight line that is unparallel to the first virtual straight line. Moreover, the plurality of first modified portions may be arrayed in such a manner as to be positioned remoter from the center in the radial direction as they are positioned closer to the other surface in the thickness direction, and the plurality of second modified portions may be arrayed in such a manner as to be positioned remoter from the center in the radial direction as they are positioned closer to the other surface in the thickness direction. In addition, a second substrate may be bonded to the other surface side of the substrate directly or via a bonding layer.

Further, in the substrate processing method according to the present invention, with use of branched laser beams obtained by branching an original laser beam, forming at least part of the first modified layer and forming at least part of the second modified layer may be performed simultaneously.

In accordance with another aspect of the present invention, there is provided a bonded substrate processing method for processing a bonded substrate including a first substrate having one surface positioned at one end in a thickness direction and another surface positioned at another end and a second substrate bonded to the other surface side of the first substrate directly or via a bonding layer. The bonded substrate processing method includes forming a first modified layer in a first annular region included in the first substrate, by applying a laser beam having a wavelength transmittable through a material of the first substrate to the first substrate from the one surface side in such a manner that a focused spot on which the laser beam is focused is positioned in the first annular region, forming a second modified layer in a second annular region that is remoter from a center of the first substrate than the first annular region and that is included in the first substrate, by applying the laser beam to the bonded substrate from the one surface side in such a manner that the focused spot is positioned in the second annular region, and reducing a bonding strength between the first substrate and the second substrate in a third annular region that is remoter from the center of the first substrate than the second annular region and that is included in an interface between the first substrate and the second substrate or in the bonding layer, by applying the laser beam to the bonded substrate from the one surface side in such a manner that the focused spot is positioned in the third annular region. By the first modified layer and the second modified layer being formed, a crack developed from the first modified layer to the second modified layer is formed.

Incidentally, in the bonded substrate processing method according to the present invention, with use of branched laser beams obtained by branching an original laser beam, two or all of forming at least part of the first modified layer, forming at least part of the second modified layer, and reducing the bonding strength between the first substrate and the second substrate may be performed simultaneously.

In accordance with a further aspect of the present invention, there is provided a chip manufacturing method for manufacturing chips by dividing a workpiece including a substrate having one surface positioned at one end in a thickness direction and another surface positioned at another end. The chip manufacturing method includes, before dividing the workpiece, forming a first modified layer in a first annular region included in the substrate, by applying a laser beam having a wavelength transmittable through a material of the substrate to the substrate from the one surface side in such a manner that a focused spot on which the laser beam is focused is positioned in the first annular region, and forming a second modified layer in a second annular region that is remoter from a center of the substrate than the first annular region in a radial direction perpendicular to the thickness direction and that is included in the substrate, by applying the laser beam to the substrate from the one surface side in such a manner that the focused spot is positioned in the second annular region. By the first modified layer and the second modified layer being formed, a crack developed from the first modified layer to the second modified layer is formed.

In the present invention, with use of the laser beam, the first modified layer and the second modified layer that is remoter from the center of the substrate than the first modified layer are formed, and, by the first modified layer and the second modified layer being formed, a crack developed from the first modified layer to the second modified layer is formed. Moreover, when the substrate in which the first modified layer, the second modified layer, and the crack are formed is divided, a new crack is developed from the first modified layer and the second modified layer, and/or the existing cracks are further developed.

In this case, the portion in the vicinity of the side surface of the substrate is removed easily without being scattered, and it is unnecessary to process the substrate by a processing tool prior to the removal. Therefore, according to the present invention, it is possible to prevent the portion in the vicinity of the side surface of the substrate from being scattered as residuals and prevent increase in processing cost and processing time.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a plan view schematically illustrating an example of a substrate;

FIG. 1B is a cross-sectional view schematically illustrating the substrate illustrated in FIG. 1A;

FIG. 2 is a flowchart schematically illustrating an example of a processing method for the substrate illustrated in FIGS. 1A and 1B;

FIG. 3 is a perspective view schematically illustrating an example of a laser processing apparatus that is capable of performing the substrate processing method illustrated in FIG. 2;

FIG. 4 is a view schematically illustrating components of a laser beam applying unit included in the laser processing apparatus illustrated in FIG. 3;

FIG. 5 is a partially cross-sectional side view schematically illustrating an example of a guide processing step illustrated in FIG. 2;

FIG. 6 is a partially cross-sectional side view schematically illustrating an example of a main processing step illustrated in FIG. 2;

FIG. 7 is a flowchart schematically illustrating another example of the processing method for the substrate illustrated in FIGS. 1A and 1B;

FIG. 8A is a partially cross-sectional side view schematically illustrating an example of a removal step illustrated in FIG. 7;

FIG. 8B is a cross-sectional view schematically illustrating the substrate that has been subjected to the removal step;

FIG. 9A is a partially cross-sectional side view schematically illustrating another example of the removal step illustrated in FIG. 7;

FIG. 9B is a partially cross-sectional side view schematically illustrating the other example of the removal step illustrated in FIG. 7;

FIG. 10 is a flowchart schematically illustrating an example of a processing method for a bonded substrate including the substrate illustrated in FIGS. 1A and 1B;

FIG. 11 is a cross-sectional view schematically illustrating an example of a bonding step illustrated in FIG. 10;

FIG. 12 is a partially cross-sectional side view schematically illustrating an example of a bonding strength reduction step illustrated in FIG. 10; and

FIG. 13 is a flowchart schematically illustrating an example of a chip manufacturing method for manufacturing chips from the bonded substrate including the substrate illustrated in FIGS. 1A and 1B.

### DETAILED DESCRIPTION OF THE PREFERRED EMBODIMENT

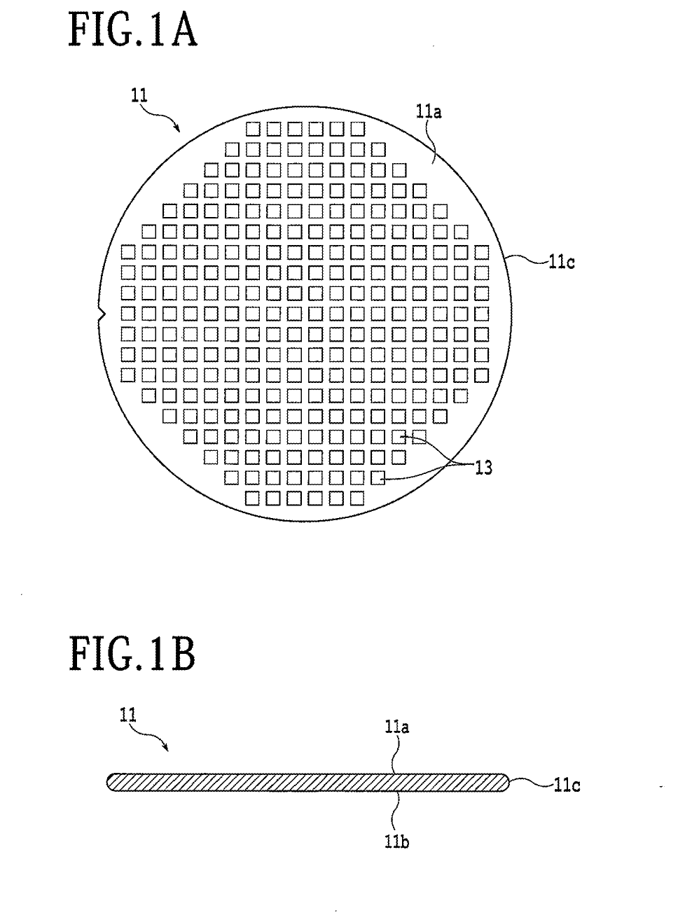

With reference to the attached drawings, an embodiment of the present invention is described. FIG. 1A is a plan view schematically illustrating an example of a substrate (substrate 11), and FIG. 1B is a cross-sectional view schematically illustrating the substrate 11. The substrate 11 includes a front surface (another surface) 11a positioned at an end in a thickness direction and a back surface (one surface) 11b positioned at another end, and is a wafer made of Si, for example.

On the front surface 11a side of the substrate 11, a plurality of devices 13 are provided. Each of the devices 13 includes, for example, a semiconductor device for use in ICs, semiconductor memories, or complementary metal oxide semiconductor (CMOS) image sensors.

The plurality of devices 13 are arranged in a matrix manner. That is, boundaries of the plurality of devices 13 extend in a lattice manner. Further, parts of the boundaries extending rectilinearly are also called planned dividing lines. Moreover, the substrate 11 is chamfered. In other words, a side surface 11c of the substrate 11 is curved into an outwardly protruding shape.

Note that there are no limitations on the material, shape, structure, size, and the like of the substrate 11. The substrate 11 may be a wafer including a semiconductor material (for example, silicon carbide (SiC), gallium nitride (GaN), or the like) instead of Si, for example. Similarly, there are no limitations on the type, number, shape, structure, size, layouts, and the like of the plurality of devices 13. Further, the substrate 11 may be integrated with a ring frame (not illustrated) via a support member (not illustrated) including an adhesive layer adhering to the front surface 11a.

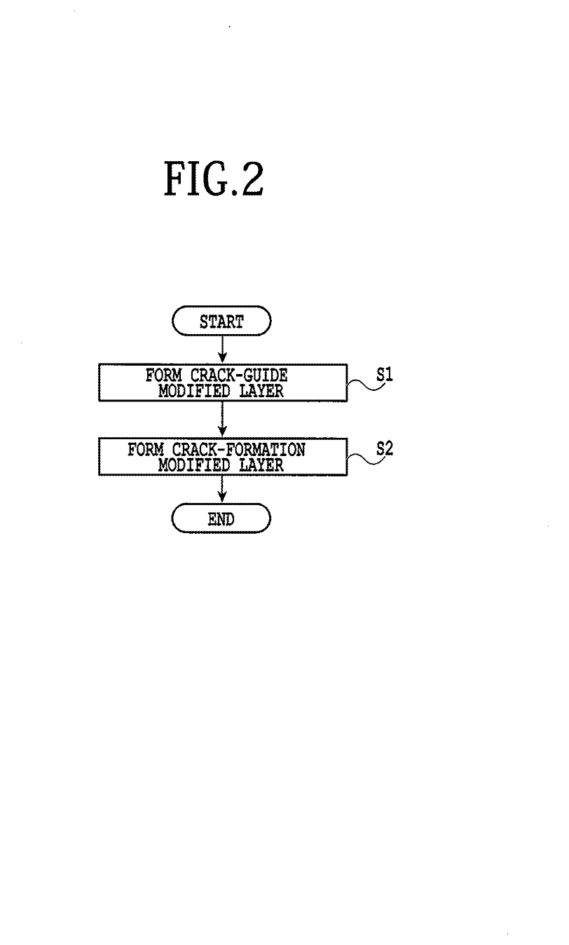

FIG. 2 is a flowchart schematically illustrating an example of a processing method for the substrate. In this method, with use of a laser beam having a wavelength transmittable through the material of the substrate 11, a crack-guide modified layer (second modified layer) is formed inside the substrate 11 (guide processing step S1), and thereafter, a crack-formation modified layer (first modified layer) is formed inwardly of the crack-guide modified layer (main processing step S2).

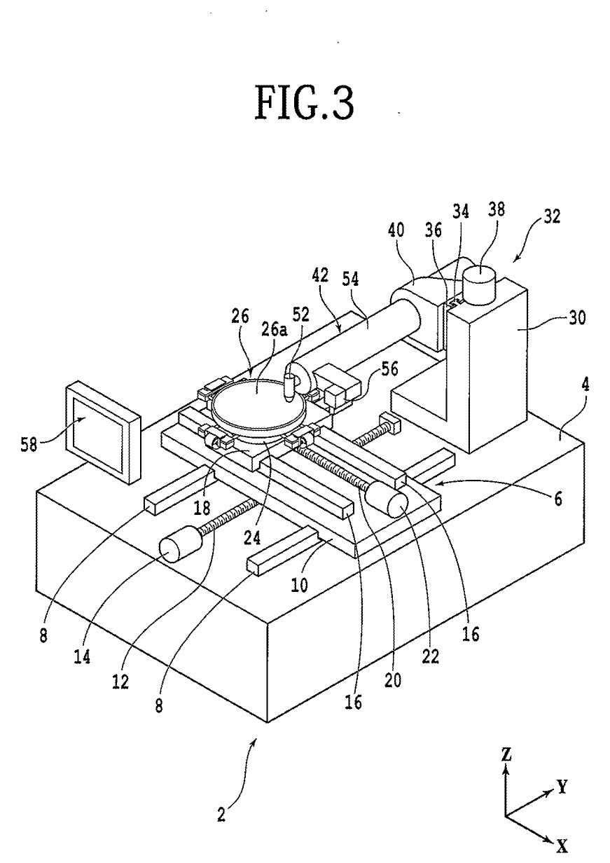

FIG. 3 is a perspective view schematically illustrating an example of a laser processing apparatus (laser processing apparatus 2) that is capable of performing the substrate processing method illustrated in FIG. 2. Note that, in FIG. 3, a direction (X-direction) indicated by an arrow X and a direction (Y-direction) indicated by an arrow Y are directions perpendicular to each other in a horizontal plane and that a direction (Z-direction) indicated by an arrow Z is a direction (vertical direction) perpendicular to the X-direction and the Y-direction.

The laser processing apparatus 2 includes a base 4 that supports various components thereon. A horizontal movement mechanism 6 is provided on an upper surface of the base 4. Further, the horizontal movement mechanism 6 includes a pair of guide rails 8 that are fixed to the upper surface of the base 4 and extend along the Y-direction. A Y-direction movable plate 10 is coupled to the pair of guide rails 8 on the upper surface side of the guide rails 8 in such a manner as to be slidable along the pair of guide rails 8.

Between the pair of guide rails 8, a screw shaft 12 extending along the Y-direction is provided. The screw shaft 12 has one end portion coupled to a motor 14 for rotating the screw shaft 12. Further, on a surface of the screw shaft 12 in which a spiral groove is formed, a nut (not illustrated) accommodating balls that roll on the surface of the rotating screw shaft 12 is provided, constituting a ball screw. That is, when the screw shaft 12 is rotated, the balls circulate through the nut, moving the nut along the Y-direction.

The nut is fixed to the lower surface side of the Y-direction movable plate 10. Hence, when the screw shaft 12 is rotated by the motor 14, the Y-direction movable plate 10 is moved along the Y-direction together with the nut. Further, a pair of guide rails 16 extending along the X-direction is fixed to an upper surface of the Y-direction movable plate 10. An X-direction movable plate 18 is coupled to the pair of guide rails 16 on the upper surface side of the guide rails 16 in such a manner as to be slidable along the pair of guide rails 16.

Between the pair of guide rails 16, a screw shaft 20 extending along the X-direction is provided. The screw shaft 20 has one end portion coupled to a motor 22 for rotating the screw shaft 20. Further, on a surface of the screw shaft 20 in which a spiral groove is formed, a nut (not illustrated) accommodating balls that roll on the surface of the rotating screw shaft 20 is provided, constituting a ball screw. That is, when the screw shaft 20 is rotated, the balls circulate through the nut, moving the nut along the X-direction.

The nut is fixed to the lower surface side of the X-direction movable plate 18. Hence, when the screw shaft 20 is rotated by the motor 22, the X-direction movable plate 18 is moved along the X-direction together with the nut. Further, on the upper surface side of the X-direction movable plate 18, a cylindrical table base 24 is provided. On an upper portion of the table base 24, a holding table 26 is provided.

The holding table 26 has, for example, a circular upper surface (holding surface) that is parallel to the X-direction and the Y-direction. A porous plate 26a is exposed at the holding surface of the holding table 26. Further, a rotation mechanism (not illustrated) is coupled to the holding table 26. The rotation mechanism includes, for example, a shaft and a motor for rotating the shaft via a pulley. When the motor is actuated, the holding table 26 rotates about a straight line that passes through the center of the holding surface along the Z-direction, as a rotational axis.

Further, the porous plate 26a is communicated with a suction source (not illustrated) such as an ejector via a flow channel or the like provided inside the holding table 26. When the suction source is actuated, pressure in the flow channel becomes negative, and a suction force acts on a space in the vicinity of the holding surface of the holding table 26. Hence, when the suction source is actuated in a state in which the substrate 11 is placed on the holding surface in such a manner as to cover the porous plate 26a, the substrate 11 is held on the holding surface.

In the Y-direction viewed from the horizontal movement mechanism 6, a support structure 30 having a side surface substantially parallel to the Y-direction and the Z-direction is provided. On the side surface of the support structure 30, a vertical movement mechanism 32 is provided. The vertical movement mechanism 32 has a pair of guide rails 34 that is fixed to the side surface of the support structure 30 and that extends along the Z-direction. A Z-direction movable plate 36 is coupled to the pair of guide rails 34 on the front surface side of the guide rails 34 in such a manner as to be slidable along the pair of guide rails 34.

Between the pair of guide rails 34, a screw shaft (not illustrated) extending along the Z-direction is provided. The screw shaft has an upper end portion (one end portion) coupled to a motor 38 for rotating the screw shaft. Further, on a surface of the screw shaft in which a spiral groove is formed, a nut (not illustrated) accommodating balls that roll on the surface of the rotating screw shaft is provided, constituting a ball screw. That is, when the screw shaft is rotated, the balls circulate through the nut, moving the nut along the Z-direction.

The nut is fixed to the back surface side of the Z-direction movable plate 36. Hence, when the screw shaft provided between the pair of guide rails 34 is rotated by the motor 38, the Z-direction movable plate 36 is moved along the Z-direction together with the nut. Further, a support member 40 is fixed to the front surface side of the Z-direction movable plate 36. The support member 40 supports a part of a laser beam applying unit 42.

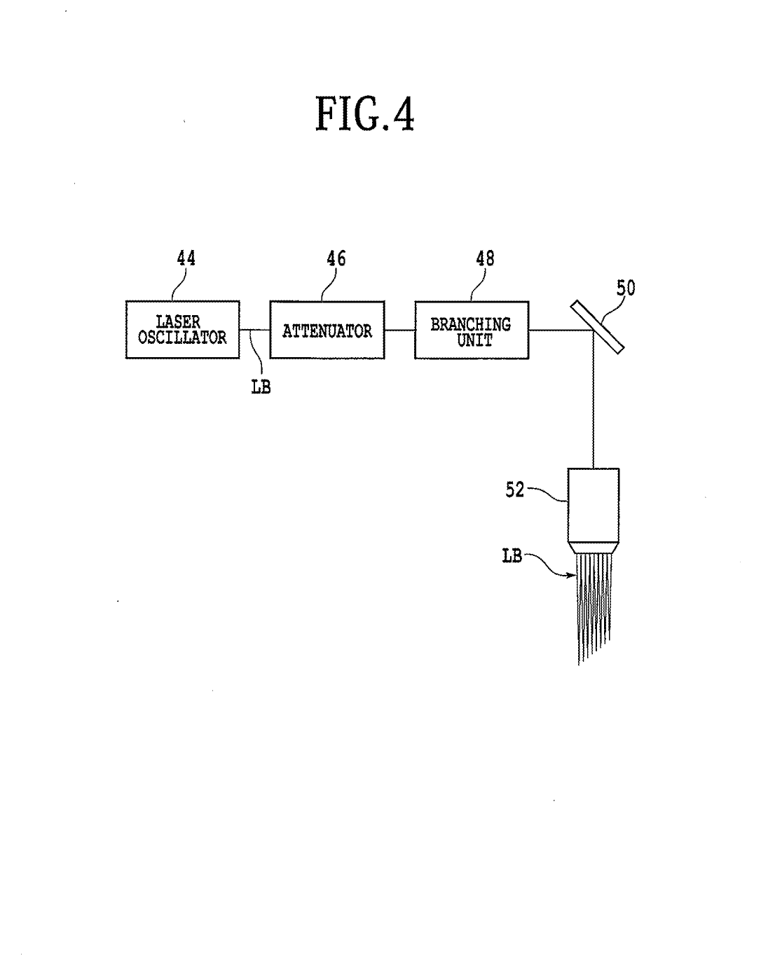

FIG. 4 is a view schematically illustrating components of the laser beam applying unit 42. Note that, in FIG. 4, some of components of the laser beam applying unit 42 are illustrated in block forms.

The laser beam applying unit 42 includes, for example, a laser oscillator 44 having a laser medium such as neodymium-doped yttrium aluminum garnet (Nd:YAG). The laser oscillator 44 emits a laser beam having a wavelength (for example, 1064 nm or 1342 nm) transmittable through the material (specifically, Si) of the substrate 11.

The laser beam emitted from the laser oscillator 44 is adjusted in an attenuator 46 in such a manner that output power of the laser beam has a predetermined value (for example, 2 W), and is then supplied to a branching unit 48. The branching unit 48 has, for example, a spatial light modulator including a liquid crystal phase control element which is referred to as a liquid crystal on silicon (LCoS) and/or a diffraction optical element (DOE).

The branching unit 48 branches an original laser beam LB obtained after the output power is adjusted in the attenuator 46. For example, the branching unit 48 branches the original laser beam LB adjusted in the attenuator 46, in such a manner that the branched laser beams LB emitted from a head 52, which is described later, form a plurality of (for example, eight) focused spots whose positions (coordinates) in a plane (XY coordinate plane) parallel to the X-direction and the Y-direction are different from each other and whose positions (heights) in the Z-direction are different from each other.

The laser beams LB branched in the branching unit 48 are reflected by a mirror 50 and guided to the head 52. The head 52 houses, for example, a focusing lens (not illustrated) that focuses the laser beams LB. The laser beams LB focused by the focusing lens are emitted toward the holding surface side of the holding table 26.

Note that, as illustrated in FIG. 3, the head 52 is mounted on a front end of a cylindrical housing 54. Further, the support member 40 is fixed to a side surface on a rear side of the housing 54. Moreover, an image capturing unit 56 is fixed to a side surface on a front side of the housing 54.

The image capturing unit 56 includes, for example, a light source such as a light-emitting diode (LED), an objective lens, and an image capturing device such as a charge-coupled device (CCD) image sensor or a CMOS image sensor.

Further, a cover (not illustrated) is mounted on the base 4 in such a manner as to cover the above-described components. Moreover, on an outer surface of the cover, a touch panel 58 is provided. The touch panel 58 includes, for example, an input device such as a touch sensor of a capacitance type or a resistive film type and a display device such as a liquid crystal display or an organic electroluminescence (EL) display, and functions as a user interface.

The laser processing apparatus 2 performs the substrate processing method illustrated in FIG. 2, in the following order, for example. Specifically, first, the substrate 11 is placed on the holding table 26 in such a manner that the back surface 11b is exposed and the porous plate 26a is covered. Next, the suction source communicated with the porous plate 26a is actuated in such a manner that the substrate 11 is held on the holding surface of the holding table 26.

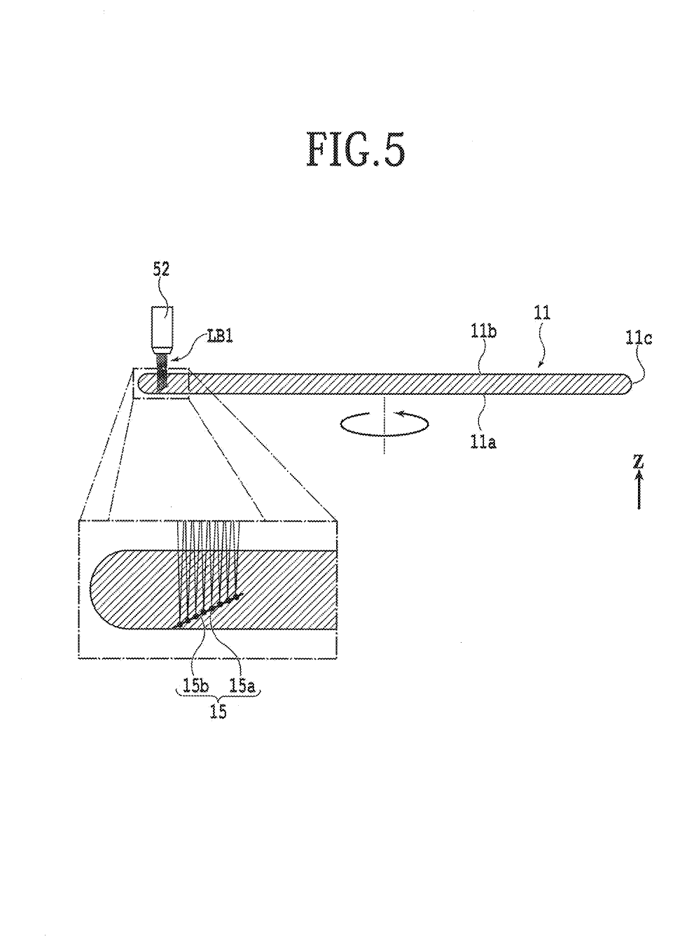

Then, the guide processing step S1 is performed. FIG. 5 is a partially cross-sectional side view schematically illustrating an example of the guide processing step S1. In the guide processing step S1 of this example, first, the image capturing unit 56 captures the back surface 11b side of the substrate 11 to form an image. Next, with reference to this image, the horizontal movement mechanism 6 is operated in such a manner that the head 52 of the laser beam applying unit 42 is positioned directly above an annular region (second annular region) positioned inwardly of the side surface 11c of the substrate 11.

Subsequently, the laser beam applying unit 42 is operated in such a manner as to apply, to the substrate 11, laser beams LB1 branched such that the plurality of focused spots to be formed are closer to the front surface 11a of the substrate 11 as they are closer to the side surface 11c. For example, from the head 52 of the laser beam applying unit 42, the laser beams LB1 branched in such a manner as to form the plurality of (for example, eight) focused spots spaced at equal intervals from each other in the thickness direction (Z-direction) and spaced at equal intervals from each other in a radial direction (direction perpendicular to the Z-direction) of the substrate 11 are emitted.

Note that the plurality of focused spots may be formed in such a manner that an interval in the radial direction between a pair of focused spots adjacent to each other and an interval in the thickness direction are equal to each other or different from each other. Further, output power of the original laser beam LB1, that is, the laser beam LB1 that has not yet been branched, is set to 2 W, for example, and the number of branches of the laser beam LB1 is set to eight, for example. That is, the output power of each of the laser beams LB1 at each focused spot is set to 0.25 W, for example.

Next, while the laser beam applying unit 42 is being operated, the rotation mechanism coupled to the lower portion of the holding table 26 is operated in such a manner as to cause the substrate 11 to make one revolution. That is, the laser beams LB1 are applied to the substrate 11 with its pass count being one. As a result, a crack-guide modified portion (second modified portion) 15a, which is a portion in which the crystal structure of the material of the substrate 11 is disturbed, is formed inside the substrate 11 around each of the plurality of focused spots as the center.

That is, in a cross section parallel to the thickness direction of the substrate 11, a plurality of crack-guide modified portions 15a linearly arrayed are formed inside the substrate 11. Note that, in this cross section, an acute angle formed between a straight line (second virtual straight line) parallel to a direction in which the plurality of crack-guide modified portions 15a are arrayed and a plane (XY plane) parallel to the X-direction and the Y-direction is, for example, 20° to 55°.

Further, when the plurality of crack-guide modified portions 15a are formed inside the substrate 11, the volume of the substrate 11 expands, thereby producing internal stress in the substrate 11. Then, inside the substrate 11, cracks 15b are developed from the crack-guide modified portions 15a in such a manner that the internal stress is relieved. As a result, a crack-guide modified layer (second modified layer) 15 that includes the plurality of crack-guide modified portions 15a and the cracks 15b developed from the respective crack-guide modified portions 15a is formed inside the substrate 11.

Note that, in the guide processing step S1, the laser beams LB1 may be applied in such a manner that the plurality of crack-guide modified portions 15a are formed inside the substrate 11 but the cracks 15b are not developed from the respective crack-guide modified portions 15a, by reducing the output power of each of the laser beams LB1 at each focused spot. That is, in the guide processing step S1, a crack-guide modified layer 15 that does not include the cracks 15b but includes only the plurality of crack-guide modified portions 15a may be formed.

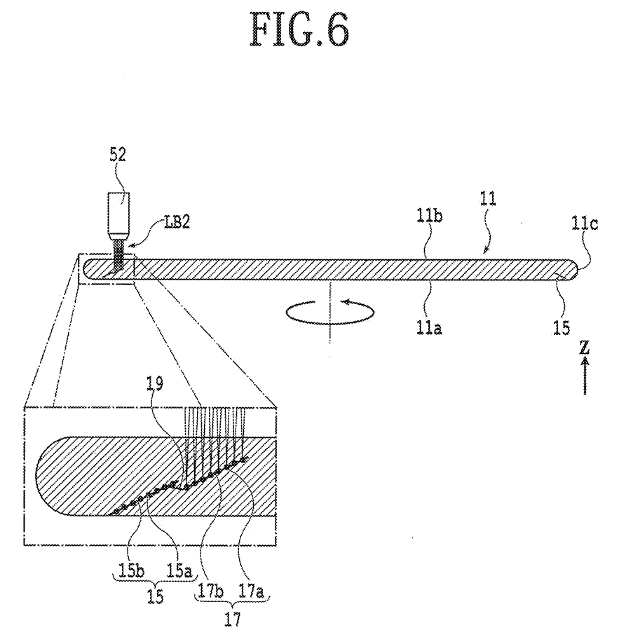

After the guide processing step S1, the main processing step S2 is performed. FIG. 6 is a partially cross-sectional side view schematically illustrating an example of the main processing step S2. In the main processing step S2 of this example, first, the horizontal movement mechanism 6 is operated in such a manner that the head 52 of the laser beam applying unit 42 is positioned directly above an annular region (first annular region) positioned slightly inwardly of the crack-guide modified layer 15 in plan view.

Next, the laser beam applying unit 42 is operated in such a manner as to apply, to the substrate 11, laser beams LB2 branched such that a plurality of focused spots to be formed are closer to the front surface 11a of the substrate 11 as they are closer to the side surface 11c. For example, from the head 52 of the laser beam applying unit 42, the laser beams LB2 branched in such a manner as to form the plurality of (for example, eight) focused spots spaced at equal intervals from each other in the thickness direction (Z-direction) and spaced at equal intervals from each other in the radial direction (direction perpendicular to the Z-direction) of the substrate 11 are emitted.

Further, the plurality of focused spots are formed in such a manner that most or all of them are closer to the back surface 11b of the substrate 11 than the crack-guide modified portion(s) 15a (crack-guide modified portion(s) 15a on the top) that is (are) close to the back surface 11b among the plurality of crack-guide modified portions 15a. In other words, the plurality of focused spots may be formed in such a manner that the focused spot that is closest to the front surface 11a of the substrate 11 is closer to the front surface 11a than the crack-guide modified portion(s) 15a on the top or is closer to the back surface 11b than the crack-guide modified portion(s) 15a on the top.

Note that the plurality of focused spots may be formed in such a manner that an interval in the radial direction between a pair of focused spots adjacent to each other and an interval in the thickness direction are equal to each other or different from each other. Further, output power of the original laser beam LB2, that is, the laser beam LB2 that has not yet been branched, and the number of branches of the laser beam LB2 may be the same as those of the laser beam LB1 in the guide processing step S1 or may be different from them. That is, the output power of each of the laser beams LB2 at each focused spot may be set to, for example, 0.25 W or may be set to other values.

Next, while the laser beam applying unit 42 is being operated, the rotation mechanism coupled to the lower portion of the holding table 26 is operated in such a manner as to cause the substrate 11 to make n (n is a natural number and is, for example, three) revolution(s). That is, the laser beams LB2 are applied to the substrate 11 with its pass count being n (for example, three). As a result, a crack-formation modified portion (first modified portion) 17a, which is a portion in which the crystal structure of the material of the substrate 11 is disturbed, is formed inside the substrate 11 around each of the plurality of focused spots as the center.

That is, in a cross section parallel to the thickness direction of the substrate 11, a plurality of crack-formation modified portions 17a linearly arrayed are formed inside the substrate 11. Note that, in this cross section, an acute angle formed between a straight line (first virtual straight line) parallel to a direction in which the plurality of crack-formation modified portions 17a are arrayed and the XY plane is, for example, 20° to 55°.

Further, the first virtual straight line is parallel to the second virtual straight line described above, for example. Alternatively, the first virtual straight line may be unparallel to the second virtual straight line. For example, the acute angle formed between the first virtual straight line and the XY plane may be larger than the acute angle formed between the second virtual straight line and the XY plane. Specifically, the acute angle formed between the first virtual straight line and the XY plane may be, for example, 20° to 30° and, at the same time, the acute angle formed between the second virtual straight line and the XY plane may be, for example, 45° to 55°.

Further, when the plurality of crack-formation modified portions 17a are formed inside the substrate 11, the volume of the substrate 11 expands, thereby producing internal stress in the substrate 11. Then, inside the substrate 11, cracks 17b are developed from the crack-formation modified portions 17a in such a manner that the internal stress is relieved. As a result, a crack-formation modified layer (first modified layer) 17 that includes the plurality of crack-formation modified portions 17a and the cracks 17b developed from the respective crack-formation modified portions 17a is formed inside the substrate 11.

In addition, when the crack-guide modified layer 15 and the crack-formation modified layer 17 are formed inside the substrate 11, a crack 19 developed from the crack-formation modified layer 17 to the crack-guide modified layer 15 is preferentially formed. In other words, in a case where the crack-guide modified layer 15 and the crack-formation modified layer 17 are formed inside the substrate 11, formation of cracks developed in a direction other than the direction from the crack-formation modified layer 17 to the crack-guide modified layer 15 is prevented.

In the substrate processing method illustrated in FIG. 2, with use of the laser beams LB1 and the laser beams LB2, the crack-formation modified layer 17 and the crack-guide modified layer 15 that is remoter from the center of the substrate 11 than the crack-formation modified layer 17 are formed, and, by the crack-formation modified layer 17 and the crack-guide modified layer 15 being formed, the crack 19 developed from the crack-formation modified layer 17 to the crack-guide modified layer 15 is formed.

Further, when the substrate 11 in which the crack-formation modified layer 17, the crack-guide modified layer 15, and the crack 19 are formed is divided, new cracks are likely to be developed from the crack-formation modified layer 17 and the crack-guide modified layer 15, and/or the existing cracks 15b, 17b, and 19 are likely to be further developed.

Therefore, in the substrate processing method illustrated in FIG. 2, the portion in the vicinity of the side surface 11c of the substrate 11 is removed easily without being scattered, and it is unnecessary to process the substrate 11 by a processing tool prior to the removal. As a result, according to the substrate processing method illustrated in FIG. 2, it is possible to prevent the portion in the vicinity of the side surface 11c of the substrate 11 from being scattered as residuals and prevent increase in processing cost and processing time.

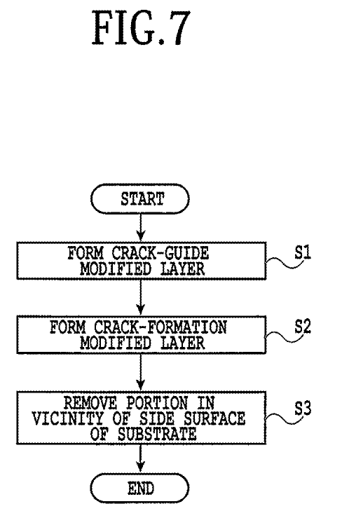

FIG. 7 is a flowchart schematically illustrating another example of the substrate processing method. In this method, after the guide processing step S1 and the main processing step S2 are performed in this order, the portion in the vicinity of the side surface 11c of the substrate 11 is removed (removal step S3).

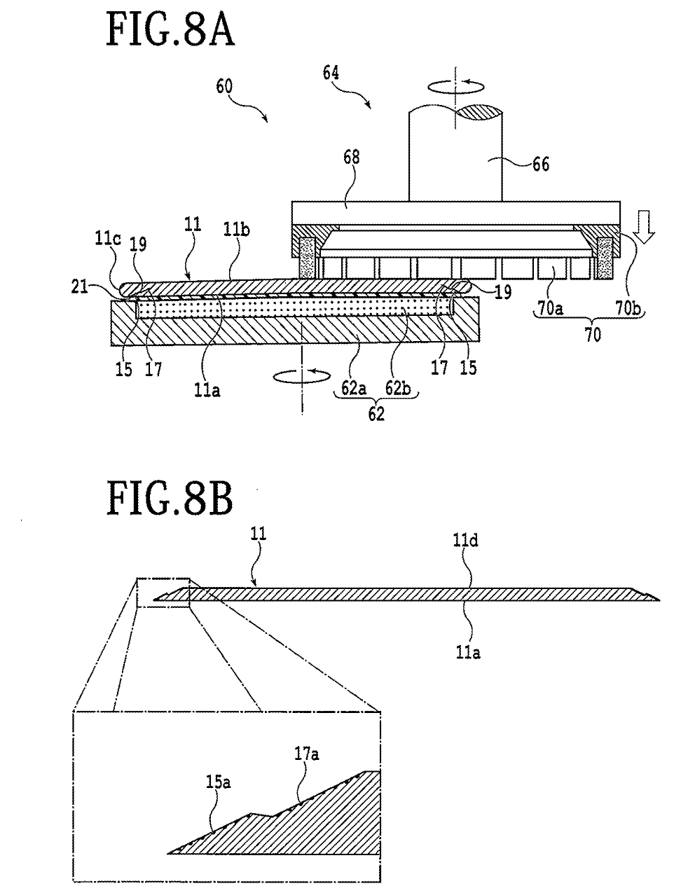

FIG. 8A is a partially cross-sectional side view schematically illustrating an example of the removal step S3, and FIG. 8B is a cross-sectional view schematically illustrating the substrate 11 that has been subjected to the removal step S3. The removal step S3 is performed in a grinding apparatus 60, for example. The grinding apparatus 60 includes a holding table 62.

The holding table 62 includes a frame 62a made of, for example, ceramic. The frame 62a includes a bottom wall shaped as a circular plate and a cylindrical side wall erected from the bottom wall. Further, on the upper surface side of the frame 62a, a recessed portion shaped as a circular plate defined by the bottom wall and the side wall is formed. Moreover, in the bottom wall of the frame 62a, a flow channel (not illustrated) opening in a bottom surface of the recessed portion is formed, and the flow channel is communicated with a suction source (not illustrated) such as an ejector.

In addition, to the recessed portion formed on the upper surface side of the frame 62a, a porous plate 62b shaped as a circular plate having a diameter substantially equal to a diameter of the recessed portion is fixed. The porous plate 62b is made of, for example, porous ceramic. Further, an upper surface of the porous plate 62b and an upper surface (holding surface of the holding table 62) of the side wall of the frame 62a have a shape (shape in which the center protrudes relative to the outer circumference) corresponding to a lateral surface of a cone.

Moreover, when the suction source communicated with the flow channel formed inside the frame 62a is actuated, pressure in the flow channel becomes negative, and a suction force acts on a space in the vicinity of the holding surface of the holding table 62. Hence, when the suction source is actuated in a state in which the substrate 11 is placed on the holding surface via a protective tape 21 adhering to the front surface 11a in such a manner as to cover the porous plate 62b, the substrate 11 is held on the holding surface.

In addition, a rotation mechanism (not illustrated) is coupled to the holding table 62. The rotation mechanism includes, for example, a shaft and a motor for rotating the shaft via a pulley. When the motor is actuated, the holding table 62 rotates about a straight line that passes through the center of the holding surface, as a rotational axis.

Further, a tilt adjusting mechanism (not illustrated) is coupled to the holding table 62. The tilt adjusting mechanism includes, for example, one fixed shaft and two movable shafts that are each movable (that can be lifted and lowered) along the vertical direction. Moreover, the fixed shaft and the two movable shafts support the holding table 62 via a table base (not illustrated) and a bearing (not illustrated). When at least one of the two movable shafts is lifted or lowered, the tilt of the holding table 62 is changed.

In addition, a horizontal direction movement mechanism (not illustrated) is coupled to the holding table 62. The horizontal direction movement mechanism includes, for example, a ball screw and a motor coupled to a screw shaft of the ball screw. When the motor is actuated, the holding table 62 is moved along a horizontal direction.

A grinding unit 64 is provided above the holding table 62. The grinding unit 64 includes a cylindrical spindle 66 extending along the vertical direction. Further, the spindle 66 has an upper end portion (proximal end portion) coupled to a motor (not illustrated) and a lower end portion (distal end portion) being a mount 68 shaped as a circular plate.

Moreover, on the lower surface side of the mount 68, an annular grinding wheel 70 having an outer diameter substantially equal to a diameter of the mount 68 is mounted with use of a fixing member (not illustrated) such as a bolt. The grinding wheel 70 includes a plurality of grindstones 70a and a wheel base 70b having a lower surface on which the plurality of grindstones 70a are mounted discretely in an annular pattern. When the motor coupled to the upper end portion of the spindle 66 is actuated, the grinding wheel 70 rotates together with the spindle 66 about a straight line extending along the vertical direction, as a rotational axis.

Further, a vertical direction movement mechanism (not illustrated) is coupled to the grinding unit 64. The vertical direction movement mechanism includes, for example, a ball screw and a motor coupled to a screw shaft of the ball screw. When the motor is actuated, the grinding unit 64 is moved along the vertical direction.

When the removal step S3 is performed in the grinding apparatus 60, first, the substrate 11 is placed on the holding table 62 via the protective tape 21 in such a manner that the back surface 11b is exposed and the porous plate 62b is covered. Next, a suction source communicated with the porous plate 62b is actuated in such a manner that the substrate 11 is held on the holding surface of the holding table 62.

Then, the holding table 62 is moved along the horizontal direction in such a manner that a track followed by the plurality of grindstones 70a when the grinding wheel 70 is rotated overlaps the center of the holding surface of the holding table 62 in the vertical direction. Subsequently, in a state in which the holding table 62 and the grinding wheel 70 are rotated, the grinding wheel 70 is lowered until the plurality of grindstones 70a are brought into contact with the back surface 11b of the substrate 11 (see FIG. 8A).

As a result, the back surface 11b side is ground, thereby thinning the substrate 11, new cracks are developed from the crack-guide modified layer 15 and the crack-formation modified layer 17 which are formed inside the substrate 11, and/or the existing cracks 15b, 17b, and 19 are further developed. As a result, the portion in the vicinity of the side surface 11c of the substrate 11, that is, the portion positioned outwardly of the crack-guide modified layer 15 and the crack-formation modified layer 17, is removed (see FIG. 8B).

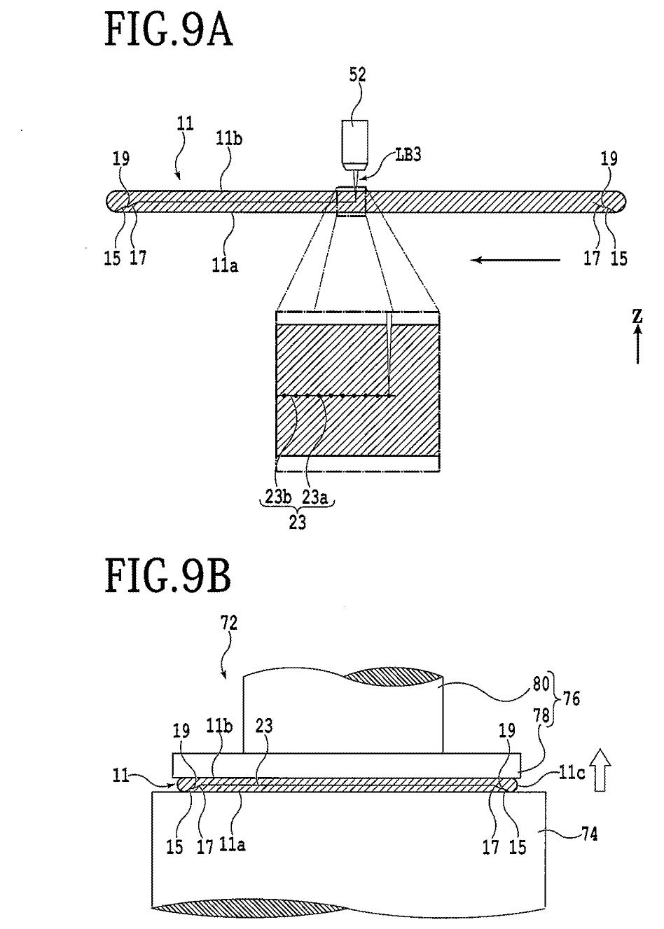

FIGS. 9A and 9B are each a partially cross-sectional side view schematically illustrating another example of the removal step S3. The removal step S3 of this example is performed in the laser processing apparatus 2 and a separating apparatus 72, for example. The separating apparatus 72 includes a holding table 74 having a structure similar to that of the holding table 26 illustrated in FIG. 3.

The holding table 74 is coupled to a table-side suction mechanism (not illustrated). The table-side suction mechanism includes, for example, a vacuum pump. When the table-side suction mechanism is operated, a suction force acts on a space in the vicinity of an upper surface (holding surface) of the holding table 74. Hence, when the table-side suction mechanism is operated in a state in which the substrate 11 is placed on the holding surface, the substrate 11 is held on the holding surface.

A separating unit 76 is provided above the holding table 74. The separating unit 76 includes a suction plate 78 having a lower surface on which a plurality of suction ports are formed. Further, the plurality of suction ports are communicated with a separating unit-side suction mechanism (not illustrated) via a suction channel formed inside the suction plate 78. The separating unit-side suction mechanism includes a vacuum pump. When the separating unit-side suction mechanism is operated, a suction force acts on a space in the vicinity of the lower surface of the suction plate 78. Hence, when the separating unit-side suction mechanism is operated in a state in which the lower surface of the suction plate 78 is in contact with or close to the back surface 11b of the substrate 11 held on the holding surface of the holding table 74, the substrate 11 is sucked upward.

Further, a vertical direction movement mechanism 80 is coupled to an upper surface of the suction plate 78. The vertical direction movement mechanism 80 includes, for example, a ball screw and a motor coupled to a screw shaft of the ball screw. When the motor is actuated, the suction plate 78 is moved along the vertical direction.

When the removal step S3 is performed in the laser processing apparatus 2 and the separating apparatus 72, first, the horizontal movement mechanism 6 is operated in such a manner that the head 52 of the laser beam applying unit 42 is positioned directly above a region located slightly inward of the crack-formation modified layer 17 formed in the substrate 11.

Next, the laser beam applying unit 42 is operated in such a manner as to apply laser beams LB3 branched such that all of the focused spots are positioned at the same position (height) in the thickness direction of the substrate 11, for example, at the same height as an upper end of the crack-formation modified layer 17. For example, from the head 52 of the laser beam applying unit 42, the laser beams LB3 branched in such a manner as to form a plurality of (for example, two to ten) focused spots arrayed at equal intervals (for example, 5 to 15 µm) in a direction (depth direction on the sheet of FIG. 9A) perpendicular to the Z-direction are emitted.

Then, while the laser beam applying unit 42 is being operated, the horizontal movement mechanism 6 is operated in such a manner as to move the holding table 26 that is holding the substrate 11 (see FIG. 9A). For example, in a case where the laser beam LB3 is branched in such a manner as to form a plurality of focused spots arrayed at equal intervals in the Y-direction, the horizontal movement mechanism 6 is operated in such a manner as to move the holding table 26 along the X-direction.

As a result, in a linear region located inwardly of the crack-formation modified layer 17 of the substrate 11, a separation modified layer 23 including a plurality of separation modified portions 23a and cracks 23b developed from the respective separation modified portions 23a is formed. Next, operation of the laser beam applying unit 42 is stopped.

Then, the horizontal movement mechanism 6 is operated in such a manner that the holding table 26 is moved along a direction perpendicular to the linear region in which the separation modified layer 23 has already been formed. That is, in the case where the laser beam LB3 is branched in such a manner as to form a plurality of focused spots arrayed at equal intervals in the Y-direction, the horizontal movement mechanism 6 is operated in such a manner that the holding table 26 is moved along the Y-direction.

Subsequently, the laser beam applying unit 42 and the horizontal movement mechanism 6 are operated in such a manner as to form the separation modified layer 23 in a linear region parallel to the linear region in which the separation modified layer 23 has already been formed. Further, a similar operation is repeated until the separation modified layer 23 is formed in the whole region located inwardly of the crack-formation modified layer 17 of the substrate 11. When the above-described processing is completed, the suction force acting on the substrate 11 disappears, and thereafter, the substrate 11 is taken out from the holding table 26.

Next, the substrate 11 is loaded into the separating apparatus 72. Specifically, in a state in which the holding table 74 and the suction plate 78 are sufficiently spaced apart from each other, the substrate 11 is placed on the holding table 74 in such a manner that the back surface 11b faces upward. Then, the table-side suction mechanism is operated in such a manner that the substrate 11 is held on the holding surface of the holding table 74.

Subsequently, the suction plate 78 is lowered until the lower surface of the suction plate 78 is in contact with or close to the back surface 11b of the substrate 11. Next, the separating unit-side suction mechanism is operated in such a manner that the back surface 11b of the substrate 11 is sucked upward. Then, the suction plate 78 is lifted in such a manner as to be spaced from the holding table 74 (see FIG. 9B).

Consequently, such an external force that separates the front surface 11a side and the back surface 11b side of the substrate 11 away from each other is applied to the substrate 11, new cracks are developed from the crack-guide modified layer 15, the crack-formation modified layer 17, and the separation modified layer 23 that are formed inside the substrate 11, and/or the existing cracks 15b, 17b, 19, and 23b are further developed. As a result, together with a portion in the vicinity of the back surface 11b of the substrate 11, the portion in the vicinity of the side surface 11c of the substrate 11, that is, the portion positioned outwardly of the crack-guide modified layer 15 and the crack-formation modified layer 17, is removed (see FIG. 8B).

Further, in a case where the removal step S3 is performed as illustrated in FIGS. 9A and 9B, the substrate 11 may be ground to flatten a surface (newly exposed surface) 11d side positioned on the side opposite to the front surface 11a of the substrate 11 (see FIG. 8B), after the removal step S3. Note that this grinding is performed similar to the removal step S3 illustrated in FIG. 8A, for example.

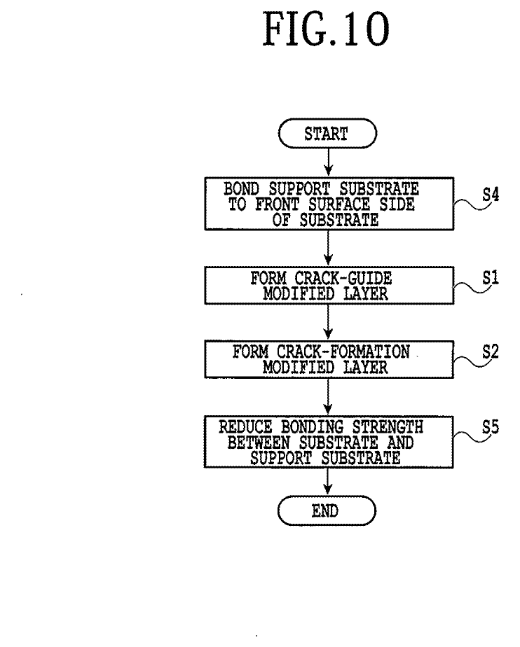

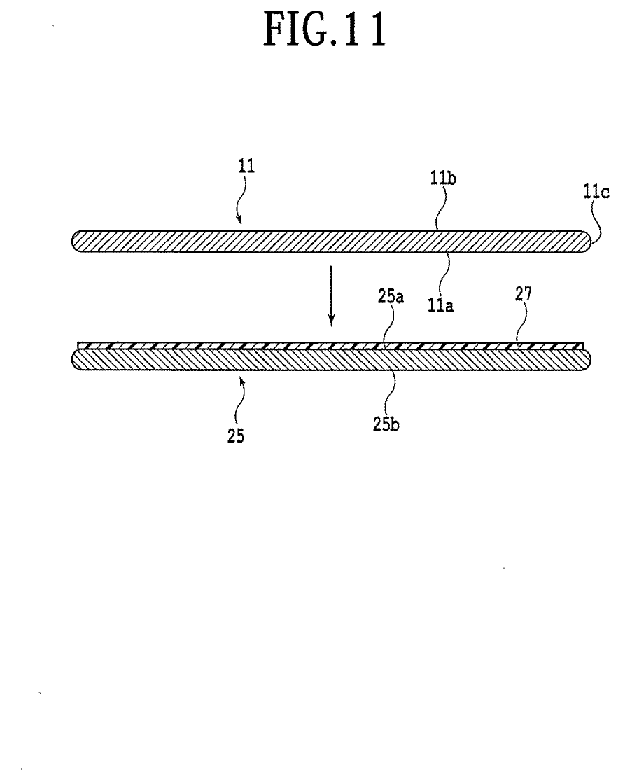

FIG. 10 is a flowchart schematically illustrating an example of a processing method for a bonded substrate including the substrate 11. In this method, first, a support substrate (second substrate) is bonded to the front surface 11a side of the substrate (first substrate) 11 (bonding step S4). FIG. 11 is a cross-sectional view schematically illustrating an example of the bonding step S4.

Note that a support substrate 25 to be bonded to the front surface 11a side of the substrate 11 has a shape similar to that of the substrate 11, for example. Further, similarly to the substrate 11, a plurality of devices may be formed on a front surface 25a side of the support substrate 25. Moreover, on the front surface 25a of the support substrate 25, a bonding layer 27 which is an acryl-based adhesive, an epoxy-based adhesive, or the like is provided, for example.

In addition, in the bonding step S4, in a state in which a back surface 25b side of the support substrate 25 is supported, the front surface 11a of the substrate 11 is pressed against the front surface 25a of the support substrate 25 via the bonding layer 27. As a result, the front surface 11a side of the substrate 11 is bonded to the support substrate 25, forming the bonded substrate.

Note that, in the bonded substrate, the substrate 11 and the support substrate 25 may be bonded directly to each other without the bonding layer 27 being interposed therebetween. In this case, the substrate 11 and the support substrate 25 are bonded to each other by, for example, an oxide film including Si formed on the front surface 11a side of the substrate 11 and an oxide film including Si formed on the front surface 25a side of the support substrate 25 being bonded to each other by a siloxane bond or a hydrogen bond.

After the bonding step S4, the guide processing step S1 and the main processing step S2 are performed. The guide processing step S1 and the main processing step S2 are performed as described above, for example.

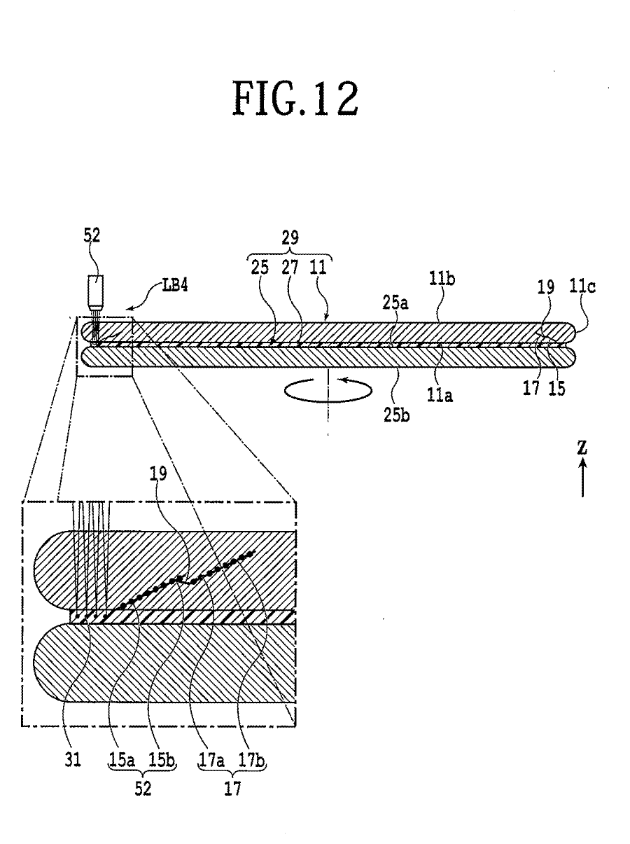

After the guide processing step S1 and the main processing step S2, the bonding strength between the substrate 11 and the support substrate 25 is reduced (bonding strength reduction step S5). FIG. 12 is a partially cross-sectional side view schematically illustrating an example of the bonding strength reduction step S5. The bonding strength reduction step S5 of this example is performed in the laser processing apparatus 2, for example.

In the bonding strength reduction step S5, first, the horizontal movement mechanism 6 is operated in such a manner that the head 52 of the laser beam applying unit 42 is positioned directly above an annular region (third annular region) that is positioned outwardly of the crack-guide modified layer 15 in plan view and that is included in a bonded substrate 29.

Next, the laser beam applying unit 42 is operated in such a manner as to apply, to the bonded substrate 29, laser beams LB4 branched such that a plurality of focused spots to be formed are arrayed along the radial direction of the substrate 11 and positioned at an interface between the substrate 11 and the support substrate 25 or in the bonding layer 27. For example, from the head 52 of the laser beam applying unit 42, the laser beams LB4 branched in such a manner as to form a plurality of (for example, four) focused spots spaced at equal intervals from each other in a direction (left-right direction on the sheet of the FIG. 12) perpendicular to the Z-direction are emitted.

Note that output power of the original laser beam LB4, that is, the laser beam LB4 that has not yet been branched, is set to 1 W, for example, and the number of branches of the laser beam LB4 is set to four, for example. That is, the output power of each of the laser beams LB4 at each focused spot is set to 0.25 W, for example. Further, among the plurality of focused spots, the focused spot positioned on the innermost side in the radial direction of the substrate 11 is formed in such a manner as to overlap the above-described second virtual straight line in a cross section parallel to the thickness direction of the substrate 11, for example.

Next, while the laser beam applying unit 42 is being operated, the rotation mechanism coupled to the lower portion of the holding table 26 is operated in such a manner as to cause the substrate 11 to make one revolution. That is, the laser beams LB4 are applied to the bonded substrate 29 with its pass count being one. As a result, a bonding-strength reduced portion 31, which is a portion whose bonding strength has been reduced, is formed around each of the plurality of focused spots as the center.

In the bonded substrate processing method illustrated in FIG. 10, the bonding-strength reduced portion 31 is formed with use of the laser beams LB4. Further, when the bonded substrate 29 in which the bonding-strength reduced portion 31 as well as the crack-formation modified layer 17, the crack-guide modified layer 15, and the crack 19 are formed is divided, new cracks are likely to be developed from the crack-formation modified layer 17 and the crack-guide modified layer 15 at an interface between the substrate 11 and the support substrate 25 or in the bonding layer 27, and/or the existing cracks 15b, 17b, and 19 are likely to be further developed.

Therefore, in the bonded substrate processing method illustrated in FIG. 10, a portion in the vicinity of the side surface 11c of the substrate 11 included in the bonded substrate 29 is removed easily without being scattered, and it is unnecessary to process the bonded substrate 29 by a processing tool prior to the removal. As a result, according to the bonded substrate processing method illustrated in FIG. 10, it is possible to prevent the portion in the vicinity of the side surface 11c of the substrate 11 from being scattered as residuals and prevent increase in processing cost and processing time.

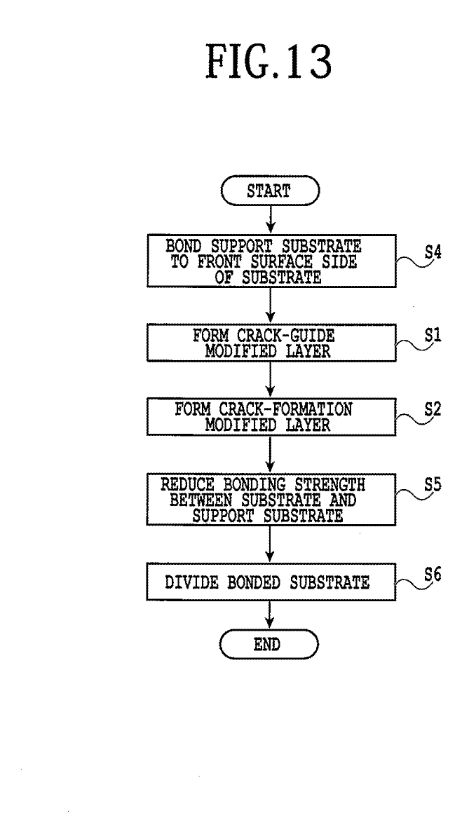

FIG. 13 is a flowchart schematically illustrating an example of chip manufacturing method for manufacturing chips from the bonded substrate 29. In this method, the bonded substrate 29 is divided (dividing step S6) after the bonded substrate processing method illustrated in FIG. 10 is performed, that is, after the bonding step S4, the guide processing step S1, the main processing step S2, and the bonding strength reduction step S5 are performed in this order.

In the dividing step S6, the bonded substrate 29 is divided by, for example, removing a portion that is included in the bonded substrate 29 and positioned at boundaries of the plurality of devices 13, with use of a processing apparatus such as a cutting apparatus, a laser processing apparatus, or a plasma etching apparatus. Alternatively, in the dividing step S6, the bonded substrate 29 may be divided by, for example, forming a modified portion at the portion that is included in the bonded substrate 29 and positioned at the boundaries of the plurality of devices 13, with use of the laser processing apparatus, and thereafter giving an external force to the bonded substrate 29 along the radial direction of the substrate 11 with use of an expanding apparatus.

In the chip manufacturing method illustrated in FIG. 13, in the dividing step S6, the portion in the vicinity of the side surface 11c of the substrate 11 included in the bonded substrate 29 is removed easily without being scattered, and it is unnecessary to process the bonded substrate 29 by a processing tool prior to the removal. As a result, according to the chip manufacturing method illustrated in FIG. 13, it is possible to prevent the portion in the vicinity of the side surface 11c of the substrate 11 from being scattered as residuals and prevent increase in processing cost and processing time.

Note that the above description is an aspect of the present invention, and the present invention is not limited thereto. For example, in the substrate processing method disclosed in the present specification, there is no limitation on the order for performing the guide processing step S1 and the main processing step S2. That is, in this method, the guide processing step S1 may be performed after the main processing step S2.

Alternatively, in the substrate processing method disclosed in the present specification, the guide processing step S1 and the main processing step S2 may be performed in parallel with each other. That is, in this method, with use of branched laser beams obtained by branching an original laser beam, forming at least part of the crack-formation modified layer 17 and forming at least part of the crack-guide modified layer 15 may be performed simultaneously.

Further, in each of the bonded substrate processing method and chip manufacturing method disclosed in the present specification, the bonding step S4 may not be performed. That is, in these methods, the guide processing step S1, the main processing step S2, and the bonding strength reduction step S5 may be performed with, as a starting material, the bonded substrate 29 including the substrate 11 and the support substrate 25 bonded to the front surface 11a of the substrate 11.

Moreover, in each of the bonded substrate processing method and chip manufacturing method disclosed in the present specification, there is no limitation on the order for performing the guide processing step S1, the main processing step S2, and the bonding strength reduction step S5. That is, in these methods, the guide processing step S1, the main processing step S2, and the bonding strength reduction step S5 may be performed in either the order of S1, S5, and S2, the order of S2, S1, and S5, the order of S2, S5, and S1, the order of S5, S1, and S2, or the order of S5, S2, and S1.

Alternatively, in each of the bonded substrate processing method and chip manufacturing method disclosed in the present specification, at least two out of the guide processing step S1, the main processing step S2, and the bonding strength reduction step S5 may be performed in parallel with each other. That is, in these method, with use of branched laser beams obtained by branching an original laser beam, two or all of forming at least part of the crack-formation modified layer 17, forming at least part of the crack-guide modified layer 15, and reducing the bonding strength between the substrate 11 and the support substrate 25 may be performed simultaneously.

In addition, the bonded substrate processing method disclosed in the present specification may include the removal step S3 performed after the guide processing step S1, the main processing step S2, and the bonding strength reduction step S5. Note that, in a case where the removal step S3 is performed as illustrated in FIGS. 9A and 9B, the substrate 11 may be ground to flatten the surface (newly exposed surface) 11d side positioned on the side opposite to the front surface 11a of the substrate 11 (see FIG. 8B), after the removal step S3.

Similarly, the chip manufacturing method disclosed in the present specification may include a removal step performed after the guide processing step S1, the main processing step S2, and the bonding strength reduction step S5 but before the dividing step S6. Note that, in a case where the removal step S3 is performed as illustrated in FIGS. 9A and 9B, the substrate 11 may be ground to flatten the surface (newly exposed surface) 11d side positioned on the side opposite to the front surface 11a of the substrate 11 (see FIG. 8B), after the removal step S3 but before the dividing step S6.

Further, the chip manufacturing method disclosed in the present specification may include the substrate processing method illustrated in FIGS. 2 or 7 and a dividing step for dividing the substrate 11 after the substrate processing method. This dividing step is performed similarly to the dividing step S6 except that the substrate 11, instead of the bonded substrate 29, is used as a workpiece.

Besides, structural and methodical details according to the above embodiment may be changed or modified without departing from the scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A substrate processing method for processing a substrate having one surface positioned at one end in a thickness direction and another surface positioned at another end, the method comprising:
forming a first modified layer in a first annular region included in the substrate, by applying a laser beam having a wavelength transmittable through a material of the substrate to the substrate from the one surface side in such a manner that a focused spot on which the laser beam is focused is positioned in the first annular region; and
forming a second modified layer in a second annular region that is remoter from a center of the substrate than the first annular region and that is included in the substrate, by applying the laser beam to the substrate from the one surface side in such a manner that the focused spot is positioned in the second annular region,
wherein, by the first modified layer and the second modified layer being formed, a crack developed from the first modified layer to the second modified layer is formed.

2. The substrate processing method according to claim 1,
wherein the first modified layer includes a plurality of first modified portions whose positions in the thickness direction and whose positions in a radial direction perpendicular to the thickness direction are different from each other in a cross section parallel to the thickness direction,
the second modified layer includes a plurality of second modified portions whose positions in the thickness direction and whose positions in the radial direction are different from each other in the cross section, and
one of the plurality of first modified portions that is closest to the other surface is closer to the other surface than one of the plurality of second modified portions that is closest to the one surface.

3. The substrate processing method according to claim 1,
wherein the first modified layer includes a plurality of first modified portions whose positions in the thickness direction and whose positions in a radial direction perpendicular to the thickness direction are different from each other in a cross section parallel to the thickness direction,
the second modified layer includes a plurality of second modified portions whose positions in the thickness direction and whose positions in the radial direction are different from each other in the cross section,
the plurality of first modified portions are arrayed, in the cross section, along a first virtual straight line, and
the plurality of second modified portions are arrayed, in the cross section, along a second virtual straight line that is unparallel to the first virtual straight line.

4. The substrate processing method according to claim 1,
wherein the first modified layer includes a plurality of first modified portions whose positions in the thickness direction and whose positions in a radial direction perpendicular to the thickness direction are different from each other in a cross section parallel to the thickness direction,
the second modified layer includes a plurality of second modified portions whose positions in the thickness direction and whose positions in the radial direction are different from each other in the cross section,
the plurality of first modified portions are arrayed in such a manner as to be positioned remoter from the center in the radial direction as they are positioned closer to the other surface in the thickness direction, and
the plurality of second modified portions are arrayed in such a manner as to be positioned remoter from the center in the radial direction as they are positioned closer to the other surface in the thickness direction.

5. The substrate processing method according to claim 1,
wherein a second substrate is bonded to the other surface side of the substrate directly or via a bonding layer.

6. The substrate processing method according to claim 1,
wherein, with use of branched laser beams obtained by branching an original laser beam, forming at least part of the first modified layer and forming at least part of the second modified layer are performed simultaneously.

7. A bonded substrate processing method for processing a bonded substrate including a first substrate having one surface positioned at one end in a thickness direction and another surface positioned at another end and a second substrate bonded to the other surface side of the first substrate directly or via a bonding layer, the method comprising:
forming a first modified layer in a first annular region included in the first substrate, by applying a laser beam having a wavelength transmittable through a material of the first substrate to the first substrate from the one surface side in such a manner that a focused spot on which the laser beam is focused is positioned in the first annular region;
forming a second modified layer in a second annular region that is remoter from a center of the first substrate than the first annular region and that is included in the first substrate, by applying the laser beam to the bonded substrate from the one surface side in such a manner that the focused spot is positioned in the second annular region; and
reducing a bonding strength between the first substrate and the second substrate in a third annular region that is remoter from the center of the first substrate than the second annular region and that is included in an interface between the first substrate and the second substrate or in the bonding layer, by applying the laser beam to the bonded substrate from the one surface side in such a manner that the focused spot is positioned in the third annular region,
wherein, by the first modified layer and the second modified layer being formed, a crack developed from the first modified layer to the second modified layer is formed.

8. The bonded substrate processing method according to claim 7,
wherein, with use of branched laser beams obtained by branching an original laser beam, two out of forming at least part of the first modified layer, forming at least part of the second modified layer, and reducing the bonding strength between the first substrate and the second substrate are performed simultaneously.

9. The bonded substrate processing method according to claim 7,
wherein, with use of branched laser beams obtained by branching an original laser beam, all of forming at least part of the first modified layer, forming at least part of the second modified layer, and reducing the bonding strength between the first substrate and the second substrate are performed simultaneously.

10. A chip manufacturing method for manufacturing chips by dividing a workpiece including a substrate having one surface positioned at one end in a thickness direction and another surface positioned at another end, the method comprising:
before dividing the workpiece,
forming a first modified layer in a first annular region included in the substrate, by applying a laser beam having a wavelength transmittable through a material of the substrate to the substrate from the one surface side in such a manner that a focused spot on which the laser beam is focused is positioned in the first annular region; and
forming a second modified layer in a second annular region that is remoter from a center of the substrate than the first annular region in a radial direction perpendicular to the thickness direction and that is included in the substrate, by applying the laser beam to the substrate from the one surface side in such a manner that the focused spot is positioned in the second annular region,
wherein, by the first modified layer and the second modified layer being formed, a crack developed from the first modified layer to the second modified layer is formed.
